(19) United States
(12) Patent Application Publication
(10) Pub. No.: US 2009/0179290 A1
(43) Pub. Date: Jul. 16, 2009

(54) Encapsulated imager packaging

(76) Inventors: Huang Shuangwu, Singapore (SG); Chia Yongpoo, Singapore (SG); Jiang Tongbi, Boise, ID (US)

Correspondence Address: DICKSTEIN SHAPIRO LLP, 1825 EYE STREET NW, Washington, DC, 20006-5403, US

(21) Appl. No.: 12/007,778

(22) Filed: Jan. 15, 2008

(51) Int. Cl. H01L 31/0203; H01L 31/18

(52) U.S. Cl. 257/434; 438/64; 257/E31.117

(57) ABSTRACT

A method and apparatus provide a leadless imager packaging structure having an integrated leadframe and a first encapsulant with an opening, which is covered by a transparent plate to form a cavity. The cavity contains an integrated circuit having a light sensitive area facing the transparent plate and which is electrically connected to the leadframe. The integrated circuit is encapsulated within the cavity by a second encapsulant.

### FIELD OF THE INVENTION

Embodiments herein relate to the field of integrated circuit packaging, and more specifically to integrated circuit imager packaging.

### BACKGROUND OF THE INVENTION

As the final step in the fabrication of a semiconductor integrated circuit, an integrated circuit is placed in packaging. The packaging serves to protect the integrated circuit from the environment and to provide a means for electrically connecting the integrated circuit to external components. As portable electronic devices have become smaller and more sophisticated, the challenge of minimizing the space used by integrated circuits and their respective packaging has continued to increase.

In conventional integrated circuit packaging techniques, the integrated circuits are packaged in a fully encapsulated manner, in which molding is used to fully enclose the integrated circuit for protection. However, if the integrated circuit is to be used as an imager device, light must be able to pass to the imager's photodetection area. Therefore, fully encapsulated packaging is not suitable for use with imager integrated circuits.

### BRIEF DESCRIPTION OF THE DRAWINGS

FIG. 1 is a cut-away side view of a leadless imager device packaging structure in accordance with an embodiment described herein.

FIG. 2a is a cut-away side view of a leadless imager device packaging structure at a stage of manufacture in accordance with an embodiment described herein.

FIG. 2b is a top-down view of the leadless imager device packaging structure at the stage of manufacture shown in FIG. 2a.

FIG. 3 is a cut-away side view of a leadless imager device packaging structure at a stage of manufacture in accordance with an embodiment described herein.

FIG. 4 is a cut-away side view of a leadless imager device packaging structure at a stage of manufacture in accordance with an embodiment described herein.

### DETAILED DESCRIPTION

In the following detailed description, reference is made to the accompanying drawings, which form a part hereof, and in which is shown by way of illustration specific embodiments described herein. These embodiments are described in sufficient detail to enable those skilled in the art to practice them, and it is to be understood that other embodiments may be utilized, and that structural, logical and electrical changes may be made.

One embodiment described herein provides a method of fabricating an imager device packaging structure using half encapsulation technology by which an integrated circuit is partially encapsulated by encapsulation material and further encapsulated by a transparent plate.

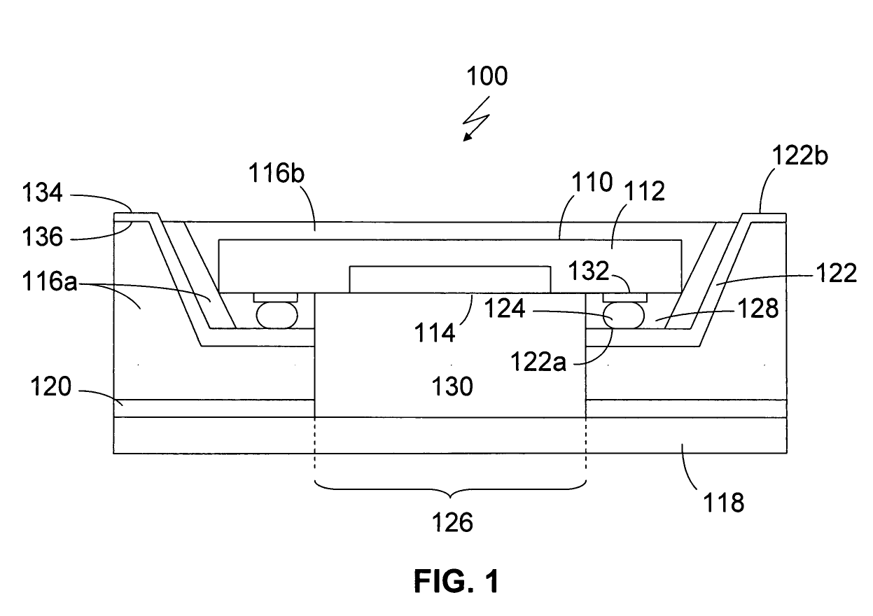

FIG. 1 shows a partial side view of a leadless imager device packaging structure 100 in accordance with an embodiment. The leadless imager device packaging structure 100 includes an integrated circuit 110 formed on a semiconductor substrate 112. The integrated circuit 110 includes a pixel array (not shown) arranged adjacent a surface 114 of the integrated circuit 110 for detecting light and may also include peripheral circuitry (not shown) for capturing, digitizing, and processing image signals produced by the pixel array.

The integrated circuit 110 is mounted inside a cavity 130 of the package formed by a first encapsulant 116a, a second encapsulant 116b, and a transparent plate 118. The transparent plate 118 is formed of a transparent material, for example, glass, such as borosilicate glass, or transparent polymer, such as polycarbonate. The transparent plate 118 is arranged such that light may enter the leadless imager device packaging structure 100 through an opening 126 in the first encapsulant 116a and impinge upon the pixel array. The transparent plate 118 is coupled to the first encapsulant 116a by a sealant 120. A leadframe 122 is arranged in first encapsulant 116a. The leadframe 122 includes first conductor traces 122a to be electrically coupled to the integrated circuit 110 and second conductor traces 122b to be electrically coupled to an external device. The second conductor traces 122b have a flat portion 134 over a flat portion 136 of the first encapsulant 116a.

The first conductor traces 122a of the leadframe 122 may be coupled to the integrated circuit 110 by interconnect materials such as bumps 124, which may be formed of an electrically conductive material such as solder, and pads 132, which are part of the integrated circuit 110 and which may be formed of electrically conducting materials such as gold, copper, or aluminum. The integrated circuit 110 is bonded to the first conductive traces 122a by the solder bumps 124. The first conductor traces 122a of the leadframe 122, the integrated circuit 110, pads 132, and bumps 124 may also be further held together using one or more adhesives 128, such as Anisotropic Conductive Film (ACF), Anisotropic Conductive Paste (ACP), Non-conductive Film (NCF), and Non-conductive Paste (NCP).

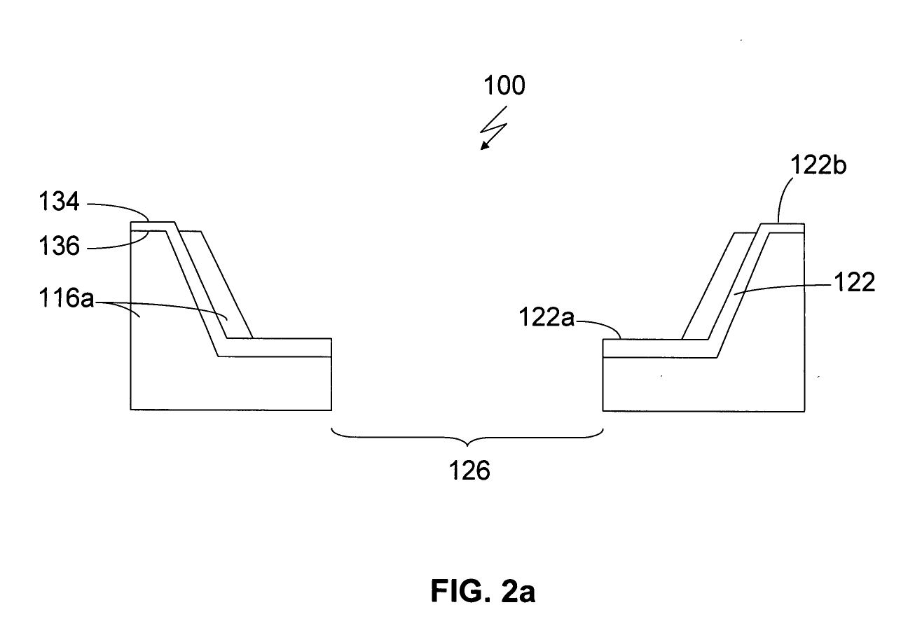

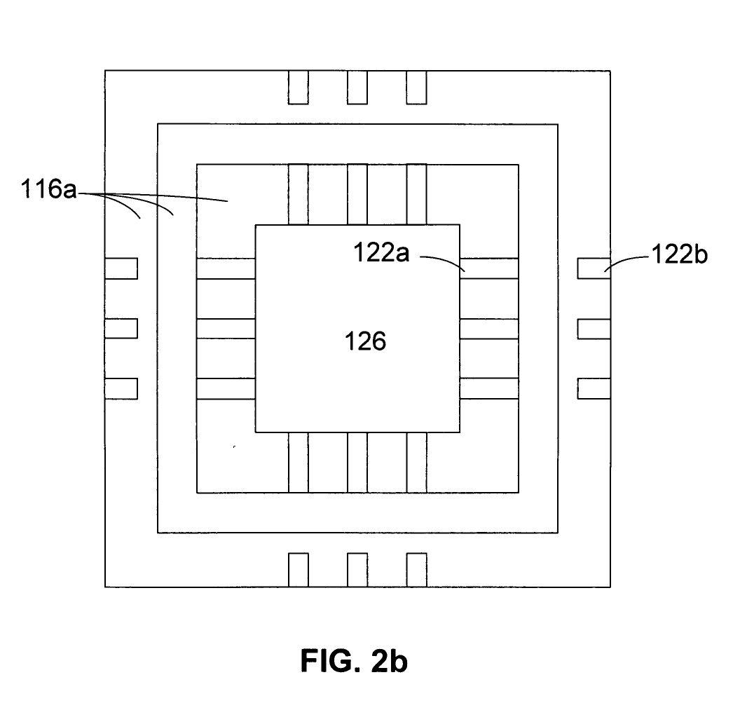

An example method of making a leadless imager device packaging structure 100 in accordance with an embodiment is now described. FIG. 2a shows a step in which the leadframe 122 is attached to the first encapsulant 116a to form an integrated structure which has an opening 126 therein. The first encapsulant 116a and the leadframe 122 surround the opening 126. The integrated structure of the first encapsulant 116a and the leadframe 122 may be accomplished through injection molding or transfer molding. The first encapsulant 116a may be formed of ceramic, plastic, epoxy, or other molding compounds known in the art. In one embodiment, the first encapsulant may be a liquid crystalline polymer or other material having a high modulus and high temperature resistance. The encapsulant may be particle-free to prevent contamination on the pixel array (FIG. 1). FIG. 2b shows a top-down view of the first encapsulant 116a, leadframe 122, and opening 126 of FIG. 2a. The embodiment shown in FIG. 2b shows three first conductor traces 122a and second conductor traces 122b on each side of the packaging structure 100, but other embodiments may have more or fewer conductor traces depending on the number of connections needed to the integrated circuit 110.

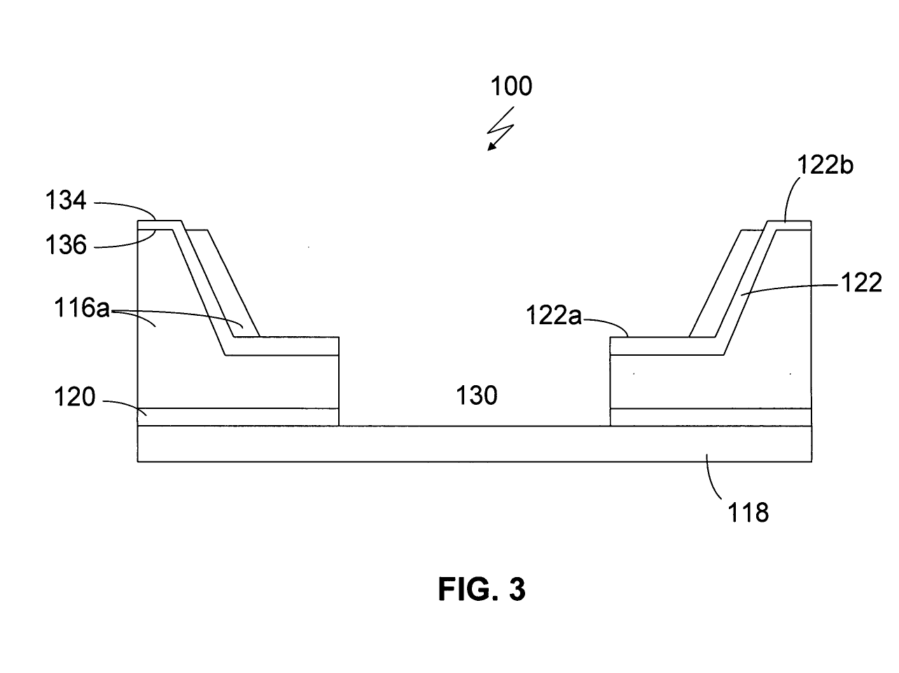

After the leadframe 122 is attached to the first encapsulant 116a, a transparent plate 118 is attached to a lower flat surface of the first encapsulant 116a as shown in FIG. 3, forming the cavity 130. The transparent plate 118 may be attached to encapsulant 116a using a sealant 120. The sealant may be, for example, an epoxy or acrylic resin, and may be cured by heat or ultraviolet light. The cavity 130 may be filled with a transparent material such as air or an inert gas, or may be a vacuum.

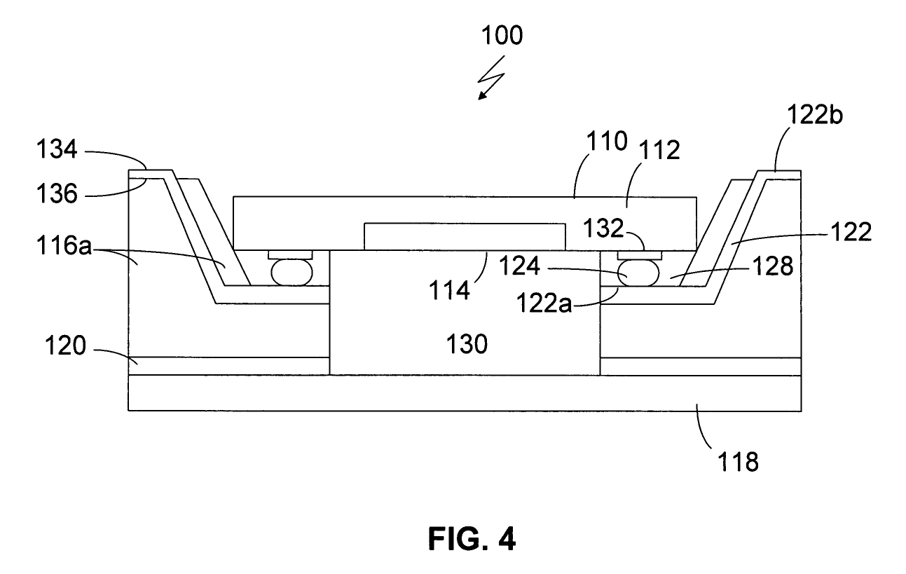

Next, as shown in FIG. 4, the integrated circuit 110 is mounted on the leadframe 122. The integrated circuit 110 is flipped upside-down in a configuration known as “flip-chip” packaging. In one embodiment, the integrated circuit 110 may be a type of integrated circuit known as a “Quad Flat package No leads” (QFN). A QFN has no leads extending out from the integrated circuit 110. Interconnect material, such as pads 132 and solder bumps 124 are used to electrically couple the integrated circuit 110 to the first conductor traces 122a using heat compression bonding, such as ultrasonic bonding, or flip-chip bonding.

One or more adhesives 128, such as Anisotropic Conductive Film (ACF), Anisotropic Conductive Paste (ACP), Non-conductive Film (NCF), and Non-conductive Paste (NCP), may be used to couple the integrated circuit 110 to the leadframe 122 and first encapsulant 116a. If ACF or NCF is used, the ACF and NCF may be pre-cut and attached to the first conductor traces 122a. If ACP, NCP, or a type of underfill is used, the ACP or NCP or underfill may be dispensed onto the first conductor traces 122a.

After mounting the integrated circuit 110, the integrated circuit may be encapsulated, for example by dispensing or by a Boschman processes, with a second encapsulant 116b, which may be the same or different material than the first encapsulant 116a used to form the cavity 130.

The integrated circuit 110 is thus partially encapsulated by the first encapsulant 116a and the second encapsulant 116b and is further encapsulated by the transparent plate 118. The integrated circuit 110 will therefore be protected within the package while still allowing light to reach the pixel array 114. Furthermore, the half-encapsulated packaging structure allows the transparent plate 118 to be located close to the pixel array, which may provide better optical performance in an imager device. In one embodiment, the leadless imager device packaging structure 100 may be fabricated using existing leadframe molding equipment and known cost effective molding materials.

The above description and drawings illustrate embodiments, which achieve the objects, features, and advantages described herein. However, it is not intended that the invention be strictly limited to the described and illustrated embodiments. For example, although embodiments have been described as being useful for producing an imager device, it should be appreciated that embodiments could be used to mount other types of integrated circuits as well, including, but not limited to, integrated circuits requiring an input light transmission. Furthermore, although the method embodiments have been described with regard to one package, it should be appreciated that multiple packages may be formed by this process at one time.

1. A method of making a packaging structure comprising:
forming an integrated structure comprising a leadframe and a first encapsulant, the structure having an opening therethrough;
attaching a transparent plate to the structure to cover the opening such that the leadframe, first encapsulant, and transparent plate form a cavity;
arranging an integrated circuit having a light sensitive area inside the cavity with the light sensitive area facing the transparent plate and electrically coupling the integrated circuit to the leadframe; and
encapsulating the integrated circuit inside the cavity using a second encapsulant.

2. The method of claim 1, wherein the light sensitive area comprises a pixel array for detecting light and wherein the pixel array is aligned with the opening and the transparent plate so that light may pass through the transparent plate and impinge upon the pixel array.

3. The method of claim 2, further comprising electrically coupling the leadframe to a side of the integrated circuit upon which the pixel array is located.

4. The method of claim 1, further comprising attaching the transparent plate to the structure using a sealant.

5. The method of claim 1, further comprising electrically coupling the integrated circuit to the leadframe via solder.

6. The method of claim 1, wherein the integrated circuit is adhered to the leadframe by a material selected from the group comprising anisotropic conductive film, anisotropic conductive paste, non-conductive film, and non-conductive paste.

7. The method of claim 1, further comprising filling the cavity with a transparent material.

8. The method of claim 7, wherein the transparent material comprises a gas.

9. The method of claim 8, wherein the gas comprises air.

10. The method of claim 1, wherein the integrated structure is formed by injection molding or transfer molding.

11. The method of claim 1, wherein the lead frame does not extend past an edge of the first encapsulant.

12. The method of claim 1, wherein the first encapsulant and the second encapsulant comprise the same material.

13. A method of making an imager comprising:
forming an integrated structure comprising a leadframe and a first encapsulant for external electrical connection, the structure having a planar surface and comprising an opening therein, wherein the leadframe comprises conductive traces that do not extend beyond the first encapsulant;
attaching a transparent plate to the planar surface of the structure to cover the opening such that the leadframe, first encapsulant, and transparent plate form a cavity;
arranging an imager device comprising a pixel array inside the cavity such that the pixel array is facing the transparent plate;
electrically coupling the imager device to the leadframe; and
encapsulating the imager device inside the cavity using a second encapsulant.

14. A packaging structure, comprising:
an integrated structure comprising a leadframe and a first encapsulant, the structure having an opening defined by the first encapsulant;
a transparent plate coupled to the structure over the opening such that the leadframe, first encapsulant, and transparent plate form a cavity;
an integrated circuit having a photosensitive area arranged inside the cavity such that the photosensitive area faces the transparent plate, the integrated circuit being electrically coupled to the leadframe; and
a second encapsulant encapsulating the integrated circuit inside the cavity.

15. The packaging structure of claim 14, wherein the integrated circuit comprises an imaging device and wherein the photosensitive area comprises a pixel array aligned with the transparent plate so that light may pass through the transparent plate and impinge upon the pixel array.

16. The packaging structure of claim 14, further comprising a sealant arranged between the transparent plate and the package.

17. The packaging structure of claim 14, further comprising a plurality of solder bumps electrically coupling the integrated circuit to the leadframe.

18. The packaging structure of claim 14, wherein the integrated circuit is coupled to the leadframe by a material selected from the group comprising anisotropic conductive film, anisotropic conductive paste, non-conductive film, and non-conductive paste.

19. The packaging structure of claim 14, further comprising a transparent material arranged in the cavity.

20. The packaging structure of claim 19, wherein the transparent material comprises air.

21. The packaging structure of claim 14, wherein the leadframe does not extend past an edge of the first encapsulant.

22. The packaging structure of claim 14, wherein the leadframe comprises conductive traces arranged flat against a flat surface of the first encapsulant.

23. A packaged imager device comprising:
a molded structure comprising a leadframe and a first encapsulant, the structure comprising an opening arranged in the first encapsulant, wherein the leadframe comprises conductive traces arranged on a flat surface of the structure;
a transparent plate coupled to the structure such that the leadframe, first encapsulant, and transparent plate form a cavity;
an imaging device comprising a pixel array arranged inside the cavity such that the pixel array is facing the transparent plate; and
a second encapsulant encapsulating the integrated circuit inside the cavity.
